(19) United States
(12) Patent Application Publication
(10) Pub. No.: US 2022/0181221 A1
(43) Pub. Date: Jun. 9, 2022

(54) SEMICONDUCTOR MODULE AND POWER CONVERTER

(71) Applicant: Mitsubishi Electric Corporation, Tokyo (JP)

(72) Inventors: Yoshinori YOKOYAMA, Chiyoda-ku, Tokyo (JP); Yo TANAKA, Chiyoda-ku, Tokyo (JP); Shinnosuke SODA, Chiyoda-ku, Tokyo (JP)

(73) Assignee: Mitsubishi Electric Corporation, Tokyo (JP)

(21) Appl. No.: 17/439,816

(22) PCT Filed: Jun. 3, 2019
(86) PCT No.: PCT/JP2019/022004

§ 371 Date: Sep. 16, 2021

(51) Int. Cl. H01L 23/13; H01L 21/52; H01L 23/057; H01L 25/07; H01L 25/18; H02M 7/00

(52) U.S. Cl. CPC H01L 23/13; H01L 21/52; H02M 7/003; H01L 25/072; H01L 25/18; H01L 23/057

(57) ABSTRACT

A semiconductor module and a power converter are obtained that can be miniaturized while reliably connecting a control signal electrode of a semiconductor chip to a control signal terminal. The semiconductor module includes a base member, a semiconductor chip, a positioning member, and a control signal terminal. The semiconductor chip is mounted on the base member. The semiconductor chip includes a control signal electrode. The positioning member includes a positioning portion that contacts an outer peripheral end portion of the semiconductor chip. The positioning member is disposed on the base member. The control signal terminal is fixed to the positioning member. The control signal terminal is connected to the control signal electrode.

### TECHNICAL FIELD

The present invention relates to a semiconductor module and a power converter.

### BACKGROUND ART

A semiconductor module, such as a power semiconductor module mounted in transport equipment, has conventionally been known. Such a semiconductor module is used as, for example, a component of a power converter. According to Japanese Patent Laying-Open No. 2009-105267, a metallic block is joined onto a main electrode of a semiconductor chip included in a semiconductor module. In the semiconductor module, the vicinity of a tip of an external lead terminal integrated with a resin case is directly joined to the metallic block. This eliminates the need for a relay board, leading to miniaturization of the semiconductor module.

### CITATION LIST

### Patent Literature

PTL 1: Japanese Patent Laying-Open No. 2009-105267

### SUMMARY OF INVENTION

### Technical Problem

In the semiconductor module described above, a member such as a bonding wire is used as a signal wire electrically connecting a control signal electrode for controlling an operation of the semiconductor chip to the outside of the semiconductor module. Since the bonding wire is joined to the control signal electrode by wire bonding, a region in which a junction tool used in wire bonding is movable needs to be secured in the semiconductor module. This results in insufficient miniaturization of the semiconductor module.

Moreover, the control signal electrode covers an extremely small area on a surface of the semiconductor chip, compared with a main electrode through which a large current flows. Thus, even when the control signal terminal to be joined to the control signal electrode is integrated with the resin case as in the case of the external lead terminal joined to the metallic block described above, due to insufficient relative positioning accuracy between the resin case and the semiconductor chip, it is difficult to correctly position and then connect the control signal electrode to the control signal terminal.

The present invention has been made to solve the above problem. An object of the present invention is to provide a semiconductor module and a power converter that can be miniaturized while reliably connecting a control signal electrode of a semiconductor chip to a control signal terminal.

### Solution to Problem

A semiconductor module according to the present disclosure includes a base member, a semiconductor chip, a positioning member, and a control signal terminal. The semiconductor chip is mounted on the base member. The semiconductor chip includes a control signal electrode. The positioning member includes a positioning portion that contacts an outer peripheral end portion of the semiconductor chip. The positioning member is disposed on the base member. The control signal terminal is fixed to the positioning member. The control signal terminal is connected to the control signal electrode.

The power converter according to the present disclosure includes a main conversion circuit and a control circuit. The main conversion circuit includes the semiconductor module described above. The main conversion circuit converts received power and outputs the converted power. The control circuit outputs a control signal for controlling the main conversion circuit to the main conversion circuit.

### Advantageous Effects of Invention

According to the above, the control signal terminal connected to the control signal electrode of the semiconductor chip is fixed to the positioning member. Further, the positioning member is disposed to contact the outer peripheral end portion of the semiconductor chip. A semiconductor module and a power converter are thus obtained that can be miniaturized while reliably connecting the control signal terminal of the semiconductor chip to the control signal terminal.

### BRIEF DESCRIPTION OF DRAWINGS

FIG. 1 is a schematic top view of a semiconductor module according to Embodiment 1.

FIG. 2 is a schematic sectional view taken along the line segment II-II of FIG. 1.

FIG. 3 is a schematic sectional view of a variation of the semiconductor module shown in FIG. 1.

FIG. 4 is a partial schematic top view of a semiconductor module according to Embodiment 2.

FIG. 5 is a partial schematic sectional view taken along the line segment V-V of FIG. 4.

FIG. 6 is a partial schematic sectional view of a semiconductor module according to Embodiment 3.

FIG. 7 is a partial schematic sectional view of a semiconductor module according to Embodiment 4.

FIG. 8 is a block diagram showing a configuration of a power conversion system in which a power converter according to Embodiment 5 is used.

### DESCRIPTION OF EMBODIMENTS

The embodiments of the present invention will now be described. The same or corresponding parts in the drawings have the same reference characters allotted, and description thereof will not be repeated.

### Embodiment 1

<Configuration of Semiconductor Module>

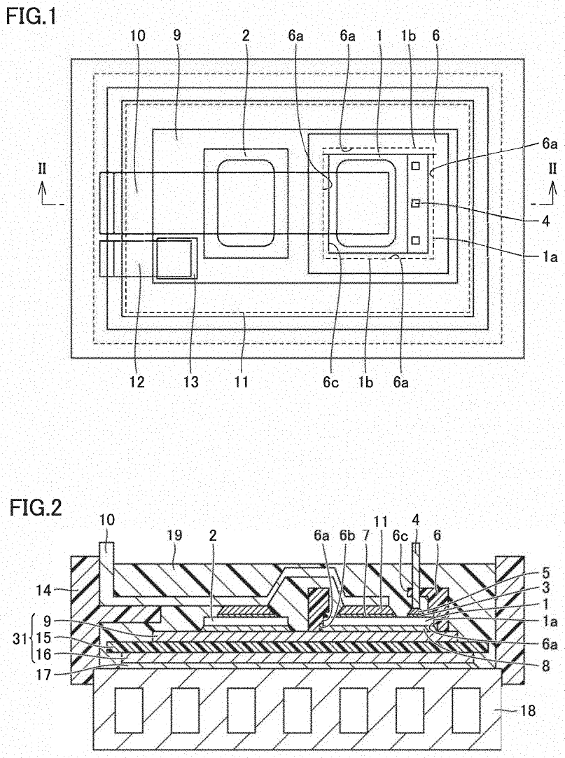

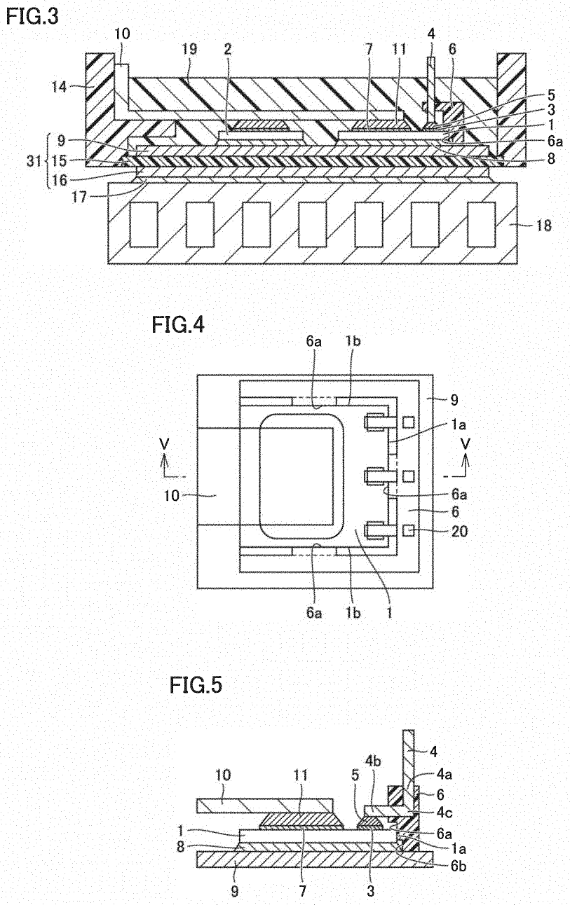

FIG. 1 is a schematic top view of a semiconductor module according to Embodiment 1. FIG. 2 is a schematic sectional view taken along the line segment II-II of FIG. 1. FIG. 3 is a schematic sectional view of a variation of the semiconductor module shown in FIG. 1.

The semiconductor module shown in FIGS. 1 and 2 mainly includes a cooler 18, a base member 31, semiconductor chips 1, 2, a positioning member 6, a control signal terminal 4, a first main terminal 10, a second main terminal 12, a case 14 made of an insulating material, and a sealing resin 19 serving as a sealing member. Base member 31 is fixed to the upper surface of cooler 18 with a joint material 17 therebetween. Base member 31 includes an insulating member 15, a circuit pattern 9 formed on the front surface of insulating member 15, and a metallic layer 16 formed on the back surface of insulating member 15. The shape of insulating member 15 is, for example, a plate shape. The planar shape of base member 31 is, for example, a quadrangular shape.

Semiconductor chips 1, 2 are joined to the front surface of circuit pattern 9 with a chip bonding material 8 therebetween. Semiconductor chips 1, 2 are power semiconductor chips, for example. Semiconductor chips 1, 2 are spaced from each other. A main electrode 7 is formed on each of the front surfaces of semiconductor chips 1, 2. First main terminal 10 is connected to main electrode 7 of each of semiconductor chips 1, 2. Main electrode 7 is connected to first main terminal 10 with a joint material 11 therebetween. Second main terminal 12 is connected to circuit pattern 9 with a joint material 13 therebetween.

First main terminal 10 and second main terminal 12 are each partially fixed to case 14. The outer peripheral ends of first main terminal 10 and second main terminal 12, which serve as external connections, are disposed outside of case 14.

Positioning member 6 is disposed so as to contact the outer peripheral end portion of semiconductor chip 1. Positioning member 6 is, for example, a block made of an insulating material and has a lateral wall portion surrounding the outer periphery of semiconductor chip 1, as shown in FIGS. 1 and 2. Positioning member 6 has an opening 6c formed on the upper surface side that is contiguous with the upper side of the lateral wall portion. A control signal terminal 4 is fixed to positioning member 6. A control signal electrode 3 is formed on the front surface of semiconductor chip 1. At least part of control signal terminal 4 is located on control signal electrode 3. Control signal terminal 4 is connected to control signal electrode 3 with a joint member 5.

The lower surface of positioning member 6 is fixed to circuit pattern 9. A recess 6b, which is recessed apart from chip bonding material 8, is formed in the lower portion on the inner peripheral side of positioning member 6, that is, in a portion of the lateral wall portion of positioning member 6 which is adjacent to circuit pattern 9. Above recess 6b, a positioning portion 6a is formed that can contact a first end 1a and a second end 1b of semiconductor chip 1. Positioning portion 6a is located closer to semiconductor chip 1 than recess 6b is to semiconductor chip 1. Positioning portion 6a may contact first end 1a and second end 1b. The inner peripheral surface of the lateral wall portion of positioning member 6, which is located above positioning portion 6a, projects toward semiconductor chip 1 than positioning portion 6a does.

First main terminal 10 is shaped to be bent apart from semiconductor chip 1 at a portion at which first main terminal 10 overlaps positioning member 6 in plan view. Case 14 surrounds the outer periphery of base member 31 and is connected to the outer peripheral portion of cooler 18. A sealing resin 19 is disposed on the inner peripheral side of case 14. Sealing resin 19 is formed to bury therein base member 31, semiconductor chips 1, 2, positioning member 6, parts of first main terminal 10 and second main terminal 12, and a part of control signal terminal 4.

Semiconductor chips 1, 2 that are power semiconductor chips are, for example, insulated gate bipolar transistors (IGBTs), free wheel diodes (FWDs), metal oxide semiconductor field effect transistors (MOSFETs), or the like. The material of the semiconductor chip is, for example, silicon (Si), silicon carbide (SiC), gallium nitride (GaN), Gallium (III) oxide (Ga₂O₃), or the like. The types and materials of semiconductor chips 1, 2 are not limited thereto. Although two semiconductor chips 1, 2 are provided in total in FIGS. 1 and 2, the number of semiconductor chips 1, 2 is not limited thereto.

Semiconductor chip 1 is provided with, on its front surface, control signal electrode 3 and main electrode 7 as described above. The types of the electrodes formed on the front surface of semiconductor chip 1 are not limited thereto. For example, only main electrode 7 is formed on the front surface of semiconductor chip 2. In this manner, any one of control signal electrode 3 and main electrode 7 may be formed on semiconductor chips 1, 2. In the view of electrical characteristics and mechanical characteristics, control signal electrode 3 and main electrode 7 may be made of at least any one of aluminum (Al), copper (Cu), silver (Ag), nickel (Ni), gold (Au), and an alloy mainly containing any of them. Although three control signal electrodes 3 are provided in FIG. 1, the number of control signal electrodes 3 is not limited thereto.

Chip bonding material 8 is provided between a back electrode (not shown) of semiconductor chip 1 and circuit pattern 9. The back electrode of semiconductor chip 1 is joined to circuit pattern 9 with chip bonding material 8. Chip bonding material 8 may be, for example, a high-temperature solder containing lead (Pb) and tin (Sn). The material for chip bonding material 8 is not limited thereto. For example, the material of chip bonding material 8 may be, for example, a Ag nanoparticle paste, a Cu nanoparticle paste, or an electrically conductive adhesive including Ag particles, Cu particles, and an epoxy resin.

Control signal terminal 4 is partially buried in positioning member 6 to be inserted thereinto to be fixed. Control signal terminal 4 projects from positioning member 6 such that one tip thereof is disposed directly above control signal electrode 3. Control signal terminal 4 is joined to control signal electrode 3 with joint member 5 therebetween.

The other tip of control signal terminal 4 projects in a direction opposite to semiconductor chip 1 from positioning member 6. Control signal terminal 4 may be made of any material having a good electrical conductivity. Such a material is, for example, an alloy including copper (Cu), aluminum (Al), and/or the like. The material for control signal terminal 4 is not limited thereto.

The material of joint member 5 is, for example, a solder material such as a lead (Pb)-free tin (Sn) solder. The material for joint member 5 is not limited thereto. The material for joint member 5 may be, for example, a sintered joint material including a Ag nanoparticle paste or a Cu nanoparticle paste, or an electrically conductive adhesive including Ag particles or Cu particles and an epoxy resin.

In FIG. 2, control signal terminal 4 is configured to have a width smaller than the width of control signal electrode 3. However, the configuration of control signal terminal 4 is not limited thereto. For example, the width of control signal terminal 4 may be equal to the width of control signal electrode 3 or larger than the width of control signal electrode 3. Although three control signal terminals 4 are provided in FIG. 1, the number of control signal terminals 4 is not limited thereto.

Positioning member 6 is disposed to surround semiconductor chip 1. Positioning member 6 has opening 6c through which the portion directly above semiconductor chip 1 is exposed. For example, positioning member 6 is fixed onto circuit pattern 9 with an adhesive (not shown) or the like. As shown in FIGS. 1 and 2, positioning member 6 is fixed onto circuit pattern 9. Since positioning portion 6a that contacts the edge, which is the outer peripheral end portion of semiconductor chip 1, is formed in positioning member 6, the arrangement of positioning member 6 relative to semiconductor chip 1 can be defined correctly. This allows control signal terminal 4 fixed to positioning member 6 to be disposed directly above control signal electrode 3. In this manner, positioning member 6 may include positioning portion 6a that is formed to surround the entire periphery of the outer peripheral end portion of semiconductor chip 1 and can contact four locations of the outer peripheral end portion of semiconductor chip 1. The planar shape of positioning member 6 may be a U-shape, and three positioning portions 6a may be formed in positioning member 6 so as to face the outer peripheral end portion of semiconductor chip 1 from three directions. FIG. 3 shows a cross-section of a positioning member having three positioning portions 6a as described above. In FIG. 3, no positioning member 6 is formed on the semiconductor chip 2 side in semiconductor chip 1. Thus, first main terminal 10 is formed linearly without being bent from above semiconductor chip 1 toward above semiconductor chip 2.

It suffices that positioning member 6 includes positioning portion 6a such that positioning portion 6a faces at least two adjacent sides at the outer peripheral end portion of semiconductor chip 1. The number of positioning portions 6a may be any number not less than three, as long as it is not less than two. The material of positioning member 6 is an insulating material that can be subjected to mold injection and has a high heat resistance. For example, such a material is polyphenyle sulfide, polybutylene terephthalate, liquid crystal resin, fluororesin, or the like.

Herein, the upper surface of semiconductor chip 1 needs to be covered with sealing resin 19 for higher insulation properties. For this reason, positioning member 6 has such a shape as not to contact the upper surface of semiconductor chip 1. It is preferable that a gap sufficient to fill sealing resin 19 be provided between the upper surface of semiconductor chip 1 and positioning member 6.

The material of first main terminal 10 and second main terminal 12 may be a material having a good electrical conductivity. Such a material is, for example, an alloy including copper (Cu), aluminum (Al), and/or the like. The material for first main terminal 10 and second main terminal 12 is not limited thereto.

The material of joint materials 11, 13 is, for example, a high-temperature solder containing lead (Pb) and tin (Sn). The material for joint materials 11, 13 is not limited thereto. The material for joint materials 11, 13 may be, for example, a sintered joint material including a Ag nanoparticle paste or a Cu nanoparticle paste, or an electrically conductive adhesive including particles, such as Ag particles or Cu particles, and an epoxy resin. Although first main terminal 10 and second main terminal 12 are formed on the surface of case 14 in the semiconductor module shown in FIGS. 1 and 2, the configurations of first main terminal 10 and second main terminal 12 are not limited thereto. First main terminal 10 and second main terminal 12 may be inserted into case 14 to be fixed.

As shown in FIG. 2, the positions of case 14 in the horizontal direction and the height direction are adjusted using the edge of cooler 18 which is the outer peripheral end portion. However, the present invention is not limited to this configuration. The positions of case 14 in the horizontal direction and the height direction may be adjusted using the outer peripheral end portion of base member 31 as shown in FIG. 3, for example, the outer peripheral end portion of insulating member 15 of base member 31. Alternatively, the positions of case 14 in the horizontal direction and the height direction may be adjusted using the outer peripheral end portion of any other member of base member 31, for example, the outer peripheral end portion of circuit pattern 9.

Insulating member 15 is, for example, a ceramic substrate. The material of the ceramic substrate may be, for example, alumina (aluminum oxide), aluminum nitride, or silicon nitride. The material of the ceramic substrate is not limited thereto.

The material of circuit pattern 9 and metallic layer 16 is, for example, copper (Cu). The material of circuit pattern 9 and metallic layer 16 is not limited thereto. The material of circuit pattern 9 and metallic layer 16 is preferably a material that can be joined to insulating member 15 by direct bonding or active metal bonding. For example, the material of circuit pattern 9 and metallic layer 16 may be a material having a high electrical conductivity.

Herein, direct bonding is a method of joining circuit pattern 9 and metallic layer 16 to insulating member 15 by direction reaction. Active metal bonding is a method of joining circuit pattern 9 and metallic layer 16 to insulating member 15 with a brazing material containing an active metal such as titanium (Ti) or zirconium (Zr). Metallic layer 16 of base member 31 is joined to cooler 18 with joint material 17 therebetween.

Insulating member 15 may be a ceramic substrate, as well as a member made of an organic material filled with a ceramic filler, for example. Such an organic material is, for example, an epoxy resin, a polyimide resin, or a cyanate resin. The material of the ceramic filler is, for example, alumina, aluminum nitride, boron nitride, or the like. In an alternative configuration, metallic layer 16 and joint material 17 may not be provided on cooler 18, and insulating member 15 may be provided on cooler 18.

Cooler 18 dissipates the heat generated during operation of the semiconductor module to the outside of the semiconductor module. Cooler 18 is thus made of a material having a good thermal conductivity. The material of cooler 18 is, for example, an alloy mainly including any of aluminum (Al) and copper (Cu). The material may be a composite material (Al—SiC) of silicon carbide (SiC) and Al. The material of cooler 18 is not limited thereto.

Metallic layer 16 is joined to cooler 18 with joint material 17 therebetween. The material of joint material 17 may be, for example, a high-temperature solder containing Pb and Sn. The material of joint material 17 may be, for example, a lead-free solder containing antimony (Sb). The material for joint material 17 is not limited thereto. The material of joint material 17 may be a sintered joint material including a Ag nanoparticle paste or a Cu nanoparticle paste, or an electrically conductive adhesive including particles, such as Ag particles or Cu particles, and an epoxy resin. As shown in FIG. 2, cooler 18 is provided with a flow path for flowing refrigerant. The flow path may be connected with a refrigerant circulation device (not shown) and a heat exchanger (not shown). The configuration of cooler 18 is not limited thereto.

Sealing resin 19 fills the region surrounded by case 14 and circuit pattern 9, that is, the inside of the casing of the semiconductor module. The material of sealing resin 19 is, for example, a silicone resin. The material of sealing resin 19 is not limited thereto. For example, the material of sealing resin 19 may be, for example, a urethane resin, an epoxy resin, a polyimide resin, a polyamide resin, a polyamide-imide resin, an acrylic resin, or a rubber material.

Sealing resin 19 may be formed of multiple sealing resins. For example, in a location where sealing resin 19 needs to fill a narrow space or the like, a gel silicone resin is used as the material of sealing resin 19. Further, in order to prevent or reduce, for example, the generation of bubbles in the gel silicone resin, an epoxy resin may be placed on top of the silicone resin to form sealing resin 19. In order to reduce a stress applied to semiconductor chip 1, also, sealing resin 19 in positioning member 6 may be an epoxy resin, whereas sealing resin 19 located within case 14 and outside of positioning member 6 may be a rubber material. In this manner, several resins individually having necessary functions may be used to form sealing resin 19.

In FIG. 2, sealing resin 19 fills the inside region surrounded by case 14 and cooler 18. Contrastingly, in FIG. 3, sealing resin 19 fills the inside region surrounded by case 14 and insulating member 15. The configurations of the members that define the inside region filled with sealing resin 19 are not limited to the examples described above.

<Positioning Method Using Positioning Member 6>

The positioning method using positioning member 6 will now be described. The position of positioning member 6 in the horizontal direction is determined by bringing positioning portion 6a of positioning member 6 into contact with first end 1a and second end 1b that are the outer peripheral end portion of semiconductor chip 1. The position of positioning member 6 in the height direction is defined by fixing the bottom surface of positioning member 6 to the surface of circuit pattern 9. Herein, the planar shape of chip bonding material 8 may be larger than the planar shape of semiconductor chip 1, as shown in FIG. 2. In this case, recess 6b is formed in the lower portion on the inner peripheral lateral surface of positioning member 6 such that the bottom surface of positioning member 6 is not disposed on chip bonding material 8. No recess 6b may be formed when the planar shape of chip bonding material 8 is the same in size as the planar shape of semiconductor chip 1. For example, a sheet-shaped electrically conductive adhesive can be used as chip bonding material 8 to cut the electrically conductive adhesive in the same size as semiconductor chip 1 through punching or the like. In this case, since the planar size of chip bonding material 8 is the same as the planar size of semiconductor chip 1, no recess 6b needs to be formed.

Positioning member 6 is fixed by connecting the lateral surface on the outer peripheral side to circuit pattern 9 with, for example, an adhesive material (not shown). However, the adhesive material may also be applied to the lower surface of positioning member 6 for firmly fixing positioning member 6 to circuit pattern 9. In this case, a projection may be formed on the bottom surface of positioning member 6, which is the surface on the circuit pattern 9 side. The adhesive material may be disposed around the projection, that is, between the bottom surface of positioning member 6 and circuit pattern 9. In this case, the projection allows the height position of positioning member 6 to be defined correctly from the surface of circuit pattern 9.

<Method of Assembling Semiconductor Module>

A method of assembling the semiconductor module according to Embodiment 1 will now be described. Base member 31, which is a joined body of circuit pattern 9, insulating member 15, and metallic layer 16, is prepared. Base member 31 is also referred to as an insulating substrate. Semiconductor chips 1, 2 are joined onto circuit pattern 9 of base member 31, which is the insulating substrate, with chip bonding material 8.

Subsequently, positioning member 6 into which control signal terminal 4 is inserted to be fixed is disposed so as to cover semiconductor chip 1 from thereabove. At this time, joint member 5 is preferably disposed on control signal electrode 3 of semiconductor chip 1 in advance. Positioning portion 6a of positioning member 6 contacts first end 1a and second end 1b that are the outer peripheral end portion of semiconductor chip 1. Further, the bottom surface of positioning member 6 is fixed to circuit pattern 9. Thus, the positions of positioning member 6 in the horizontal direction and the height direction can be determined. This allows the tip of control signal terminal 4 fixed to positioning member 6 to be positioned directly above control signal electrode 3 of semiconductor chip 1.

When a bonding wire is connected to control signal electrode 3 by conventional wire bonding, a wire and a bonding tool each need to be positioned relative to control signal electrode 3. A region in which the bonding tool is movable also needs to be secured. The method of assembling the semiconductor module according to Embodiment 1 described above, however, needs neither positioning of the wire and the bonding tool nor securing of a region in which the bonding tool is movable as described above. This leads to miniaturization of the semiconductor module.

Subsequently, joint material 17 is disposed between cooler 18 and metallic layer 16 of base member 31. Also, case 14 is disposed on cooler 18. First main terminal 10, second main terminal 12, and joint materials 11, 13 are disposed on their respective determined positions. For example, when a solder material is used as joint member 5, and joint materials 11, 13, and 17, the position of positioning member 6 relative to semiconductor chip 1 can be defined correctly using positioning portion 6a of positioning member 6, thereby positioning control signal electrode 3 and control signal terminal 4 so as to overlap each other. Also, case 14 can be positioned relative to cooler 18 or base member 31, thereby correctly positioning first main terminal 10 and second main terminal 12 relative to semiconductor chips 1, 2 and circuit pattern 9. Reflow heating is performed in this state, thus allowing control signal terminal 4, first main terminal 10, and second main terminal 12 to be fixed once while being correctly positioned, without the need for individual positioning for each terminal.

Also, the present embodiment is applicable not only to the case where there are two semiconductor chips 1, 2 as shown but also to the method of assembling the semiconductor module including two or more control signal terminals 4. In other words, each of semiconductor chips 1, having a control signal electrode, is provided with positioning member 6 including its corresponding control signal terminal 4. This allows control signal terminals 4 to be simultaneously joined to the respective control signal electrodes 3 by reflow heating or the like. Case 14, first main terminal 10, and second main terminal 12 can be disposed further, thereby allowing these main terminals to be joined simultaneously with control signal terminal 4. This can improve productivity in the step of assembling the semiconductor module.

In the configuration of the semiconductor module according to Embodiment 1, control signal terminal 4 is inserted into positioning member 6 to be fixed. Further, positioning portion 6a is disposed in positioning member 6 such that the tip of control signal terminal 4 is disposed directly above control signal electrode 3. This allows control signal terminal 4 to be correctly disposed to be joined directly above control signal electrode 3 of semiconductor chip 1. Also, the power semiconductor module can be miniaturized.

### Operations and Effects

The semiconductor module according to the present disclosure includes base member 31, semiconductor chip 1, positioning member 6, and control signal terminal 4. Semiconductor chip 1 is mounted on base member 31. Semiconductor chip 1 includes control signal electrode 3. Positioning member 6 includes positioning portion 6a that contacts the outer peripheral end portion of semiconductor chip 1. Positioning member 6 is disposed on base member 31. Control signal terminal 4 is fixed to positioning member 6. Control signal terminal 4 is connected to control signal electrode 3.

Thus, as positioning portion 6a of positioning member 6 contacts the outer peripheral end portion of semiconductor chip 1, the arrangement of positioning member 6 relative to semiconductor chip 1 can be defined correctly. The relative arrangement of control signal terminal 4 fixed to positioning member 6 relative to semiconductor chip 1 can also be determined correctly, thus allowing control signal terminal 4 to be reliably connected to control signal electrode 3. Further, this eliminates the need for securing a region in which the bonding tool used in wire bonding is movable as in the case of connecting a bonding wire to a control signal electrode, leading to miniaturization of the semiconductor module.

In the semiconductor module, positioning member 6 is fixed to base member 31. In this case, positioning member 6 can be reliably fixed to be positioned adjacent to semiconductor chip 1.

The semiconductor module includes joint member 5 that joins control signal electrode 3 to control signal terminal 4. In this case, control signal terminal 4 can be reliably fixed to control signal electrode 3 with joint member 5.

In the semiconductor module, the outer shape of the outer peripheral end portion of semiconductor chip 1 is a quadrangular shape in a plan view of semiconductor chip 1. Positioning portion 6a contacts each of two or more adjacent sides of the outer shape of the outer peripheral end portion. In this case, the arrangement of positioning member 6 relative to semiconductor chip 1 can be correctly determined.

In the semiconductor module, the outer peripheral end portion of semiconductor chip 1 includes first end 1a and second end 1b. In a plan view of semiconductor chip 1, first end 1a extends in a first direction. In the plan view of semiconductor chip 1, second end 1b extends in a direction crossing first end 1a and is contiguous with first end 1a. Positioning portion 6a includes a first portion that contacts first end 1a and a second portion that contacts second end 1b. In this case, the arrangement of positioning member 6 relative to semiconductor chip 1 can be determined correctly.

In the semiconductor module, positioning member 6 has opening 6c for exposing the surface of semiconductor chip 1 on which control signal electrode 3 is formed. In this case, the state of the connection between control signal electrode 3 and control signal terminal 4 can be checked easily through opening 6c.

### Embodiment 2

<Configuration of Semiconductor Module>

FIG. 4 is a partial schematic top view of a semiconductor module according to Embodiment 2. FIG. 5 is a partial schematic sectional view taken along the line segment V-V of FIG. 4.

The semiconductor module shown in FIGS. 4 and 5 is basically similar to the semiconductor module shown in FIGS. 1 and 2 in configuration and is different from the semiconductor module shown in FIGS. 1 and 2 in the configuration of positioning member 6 and the shape of control signal terminal 4. In other words, in the semiconductor module shown in FIGS. 4 and 5, the planar shape of positioning member 6 is a U-shape, and three positioning portions 6a are provided that contact the outer peripheral end portion of semiconductor chip 1 in three directions. Control signal terminal 4 has a bent portion 4c. Control signal terminal 4 is inserted into positioning member 6 to be fixed. Control signal terminal 4 is disposed inside positioning member 6 and has a fixed portion 4a connected to positioning member 6. Fixed portion 4a includes bent portion 4c. Control signal terminal 4 includes a terminal portion 4b, which is one tip. Terminal portion 4b projects from positioning member 6 so as to be positioned directly above control signal electrode 3. Terminal portion 4b is joined to control signal electrode 3 with joint member 5 therebetween. The other tip of control signal terminal 4 projects from positioning member 6 toward the side opposite to semiconductor chip 1.

Positioning member 6 of FIG. 4 includes positioning portion 6a that contacts first end 1a of semiconductor chip 1 and two positioning portions 6a that contact two second ends 1b of semiconductor chip 1. Positioning member 6 has, in plan view, three positioning portions 6a facing the outer peripheral end portion of semiconductor chip 1 from three directions. Although positioning portions 6a extend in three directions in FIG. 4, it suffices that two positioning portions 6a are formed, each of which is in contact with a corresponding one of first end 1a and second end 1b being two adjacent sides of semiconductor chip 1. In positioning member 6, four positioning portions 6a facing the outer peripheral end portion of semiconductor chip 1 from four directions may be formed, as shown in FIGS. 1 and 2.

As shown in FIG. 5, in the semiconductor module according to Embodiment 2, opening 6c for exposing semiconductor chip 1 is formed in positioning member 6 as in the semiconductor module shown in FIGS. 1 and 2. Further, control signal terminal 4 includes bent portion 4c. This allows the state of the junction between control signal electrode 3 and control signal terminal 4 to be checked through visual inspection.

### Operations and Effects

In the semiconductor module, the outer peripheral end portion of semiconductor chip 1 includes first end 1a and second end 1b. In a plan view of semiconductor chip 1, first end 1a extends in a first direction. In the plan view of semiconductor chip 1, second end 1b extends in a direction crossing first end 1a and is contiguous with first end 1a. Positioning portion 6a includes a first portion that contacts first end 1a and a second portion that contacts second end 1b. In this case, the arrangement of positioning member 6 relative to semiconductor chip 1 can be determined correctly.

### Embodiment 3

<Configuration of Semiconductor Module>

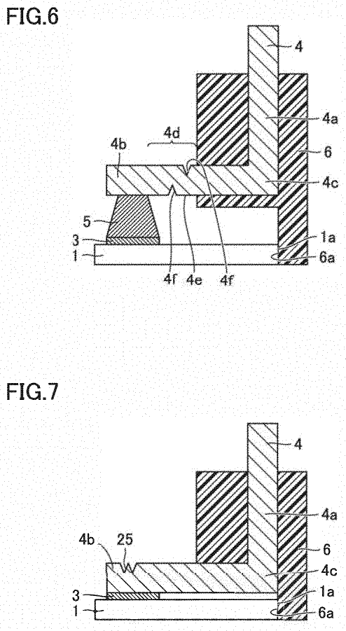

FIG. 6 is a partial schematic sectional view of a semiconductor module according to Embodiment 3. The semiconductor module shown in FIG. 6 is basically similar to the semiconductor module shown in FIGS. 4 and 5 in configuration and is different from the semiconductor module shown in FIGS. 4 and 5 in the shape of control signal terminal 4. In other words, in the semiconductor module shown in FIG. 6, control signal terminal 4 includes a position adjustment portion 4d. Position adjustment portion 4d functions to complement the height adjustment of positioning member 6. Position adjustment portion 4d includes cutouts 4f formed in a connection 4e connecting terminal portion 4b to bent portion 4c. Connection 4e extends along, for example, the upper surface of semiconductor chip 1. Cutouts 4f are formed in connection 4e. Cutout 4f is formed in each of the upper surface and the lower surface of connection 4e. As such cutouts 4f are formed, connection 4e consequently includes a portion having a thickness smaller than the thickness of any other portion of control signal terminal 4. As a result, connection 4e elastically deforms more easily than any other portion of control signal terminal 4. From a different perspective, connection 4e is less rigid than any other portion of control signal terminal 4. Alternatively, connection 4e may elastically deform more easily than any other portion of control signal terminal 4. As long as connection 4e elastically deforms more easily, cutout 4f may be formed in only any of the upper surface and the lower surface of connection 4e. Such position adjustment portion 4d can complement the position adjustment of positioning member 6 in the height direction. In other words, even when positioning member 6 becomes misaligned in the height direction due to the deformation of position adjustment portion 4d, control signal terminal 4 can be reliably contact control signal electrode 3.

Cutout 4f is formed in each of the upper surface and the lower surface of connection 4e, but may be formed in each of the left and right surfaces of connection 4e. Such position adjustment portion 4d can complement the position adjustment of positioning member 6 in the horizontal direction. In other words, even when positioning member 6 becomes misaligned horizontally due to the deformation of position adjustment portion 4d, control signal terminal 4 can reliably contact control signal electrode 3.

Position adjustment portion 4d may adopt any other configuration than cutouts 4f as described above. For example, position adjustment portion 4d may be achieved with a configuration in which position adjustment portion 4d is elastically deformable by, for example, forming connection 4e to be relatively thinner than bent portion 4c or the like, forming connection 4e to have a bellows shape, or forming connection 4e to be curved. Since control signal terminal 4 has position adjustment portion 4d, high-accurate positioning of control signal terminal 4 relative to control signal electrode 3 is enabled.

### Operations and Effects

In the semiconductor module described above, control signal terminal 4 includes fixed portion 4a, terminal portion 4b, and position adjustment portion 4d. Fixed portion 4a is fixed to positioning member 6. Terminal portion 4b is connected to control signal electrode 3. Position adjustment portion 4d changes the position of terminal portion 4b relative to fixed portion 4a in the direction from control signal electrode 3 toward terminal portion 4b. In this case, since variations in arrangement in the height direction from control signal electrode 3 toward terminal portion 4b can be accommodated by position adjustment portion 4d for control signal electrode 3 and control signal terminal 4, control signal electrode 3 can be reliably connected to control signal terminal 4.

In the semiconductor module described above, control signal terminal 4 includes connection 4e. Connection 4e connects fixed portion 4a to terminal portion 4b. Position adjustment portion 4d includes cutouts 4f formed in connection 4e. In this case, since connection 4e in which cutouts 4f are formed is deformable easily in the height direction, variations in the arrangement in the height direction can be accommodated by position adjustment portion 4d for control signal electrode 3 and control signal terminal 4. This allows control signal electrode 3 and control signal terminal 4 to be reliably connected to each other.

In the semiconductor module described above, position adjustment portion 4d is connection 4e connecting fixed portion 4a to terminal portion 4b. Connection 4e is elastically deformable in the direction from control signal electrode 3 toward terminal portion 4b. In this case, since connection 4e is elastically deformable in the height direction, variations in the arrangement in the height direction can be accommodated by connection 4e for control signal electrode 3 and control signal terminal 4. This allows control signal electrode 3 and control signal terminal 4 to be reliably connected to each other.

### Embodiment 4

<Configuration of Semiconductor Module>

FIG. 7 is a partial schematic sectional view of a semiconductor module according to Embodiment 4. The semiconductor module shown in FIG. 7 is basically similar to the semiconductor module shown in FIGS. 4 and 5 in configuration and is different from the semiconductor module shown in FIGS. 4 and 5 in the structure of connection between control signal terminal 4 and control signal electrode 3. In other words, in the semiconductor module shown in FIG. 7, terminal portion 4b of control signal terminal 4 is directly joined to control signal electrode 3. Any bonding method is applicable, and for example, control signal terminal 4 may be joined to control signal electrode 3 by ultrasonic bonding.

In a case where a wiring member is joined to an electrode by ultrasonic bonding, normally, ultrasonic vibrations are applied while pressing a bonding tool from the upper surface of the wiring member. Thus, a recess 25 is formed in the upper surface of terminal portion 4b of control signal terminal 4 as shown in FIG. 7. The configuration of control signal terminal 4 is not limited thereto. For example, terminal portion 4b of control signal terminal 4 and control signal electrode 3 may be subjected to ultrasonic bonding without forming recess 25 in the upper surface of terminal portion 4b of control signal terminal 4. In this case, a joint strength of a junction between control signal terminal 4 and control signal electrode 3 can be improved more than in Embodiment 1 to Embodiment 3.

### Operations and Effects

In the semiconductor module, control signal electrode 3 is directly joined to control signal terminal 4. In this case, a high-strength junction can be formed between control signal electrode 3 and control signal terminal 4. This can increase the reliability of joining between control signal electrode 3 and control signal terminal 4.

### Embodiment 5

In the present embodiment, the semiconductor device according to any of Embodiments 1 to 4 described above is used in a power converter. Although the present invention is not limited to a specific power converter, the case where the present invention is applied to a three-phase inverter will be described below as Embodiment 5.

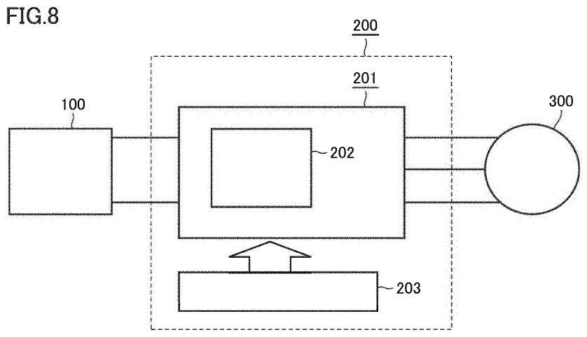

FIG. 8 is a block diagram showing a configuration of a power conversion system in which the power converter according to the present embodiment is used.

The power conversion system shown in FIG. 8 includes a power supply 100, a power converter 200, and a load 300. Power supply 100 is a direct-current (DC) power supply and supplies DC power to power converter 200. Power supply 100 may be configured of any of various components. For example, power supply 100 may be configured of a DC system, a solar battery, or a storage battery, or may be configured of a rectifier circuit or an alternating-current (AC)/DC converter connected to an AC system. Alternatively, power supply 100 may be configured of a DC/DC converter that converts DC power output from the DC system into predetermined power.

Power converter 200 is a three-phase inverter connected between power supply 100 and load 300. Power converter 200 converts DC power supplied from power supply 100 into AC power and supplies the AC power to load 300. Power converter 200 includes a main conversion circuit 201, which converts DC power into AC power and outputs the AC power, and a control circuit 203, which outputs a control signal for controlling main conversion circuit 201 to main conversion circuit 201 as shown in FIG. 8.

Load 300 is a three-phase electric motor driven by the AC power supplied from power converter 200. The use of load 300 is not limited to a particular use. Load 300 is an electric motor mounted in various types of electrical devices, which can be used as an electric motor for a hybrid vehicle, an electric vehicle, a rail vehicle, an elevator, or an air conditioner, for example.

Power converter 200 will be described below in detail. Main conversion circuit 201 includes a switching element (not shown) and a freewheeling diode (not shown). As a result of switching of the switching element, main conversion circuit 201 converts the DC power supplied from power supply 100 into AC power and supplies the AC power to load 300. Although a specific circuit configuration of main conversion circuit 201 is of various types, main conversion circuit 201 according to the present embodiment is a two-level, three-phase full-bridge circuit, and can be composed of six switching elements and six freewheeling diodes each connected in anti-parallel with a corresponding one of the six switching elements. The switching elements and the freewheeling diodes of main conversion circuit 201 are each configured of semiconductor module 202 corresponding to any one of Embodiments 1 to 4. The six switching elements are connected in series for every two switching elements to constitute upper-lower arms, and the upper-lower arms constitute the respective phases (U-phase, V-phase, W-phase) of the full-bridge circuit. The output terminals of the respective upper-lower arms, that is, three output terminals of main conversion circuit 201, are connected to load 300.

Main conversion circuit 201 includes a drive circuit (not shown) that drives each of the switching elements. The drive circuit may be built in semiconductor module 202, or may be included separately from semiconductor module 202. The drive circuit generates a drive signal for driving the switching element of main conversion circuit 201 and supplies the drive signal to a control electrode of the switching element of main conversion circuit 201. Specifically, the drive circuit outputs a drive signal for turning on the switching element and a drive signal for turning off the switching element to the control electrode of each switching element in accordance with the control signal from control circuit 203. When the switching element is kept in ON state, the drive signal is a voltage signal (ON signal) not less than a threshold voltage of the switching element, and when the switching element is kept in OFF state, the drive signal is a voltage signal (OFF signal) not greater than the threshold of the switching element.

Control circuit 203 controls the switching element of main conversion circuit 201 such that a desired amount of power is supplied to load 300. Specifically, based on the power to be supplied to load 300, control circuit 203 calculates a period of time (ON time) in which each switching element of main conversion circuit 201 is to be turned on. For example, control circuit 203 can control main conversion circuit 201 through PWM control in which ON time of the switching element is modulated in accordance with the voltage to be output. Then, control circuit 203 outputs a control command (control signal) to the drive circuit of main conversion circuit 201 such that ON signal is output to the switching element to be turned on and OFF signal is output to the switching element to be turned off at each point of time. The drive circuit outputs ON signal or OFF signal as a drive signal to the control electrode of each switching element in accordance with the control signal.

The semiconductor modules according to any of Embodiment 1 to Embodiment 4 is used as the switching element and the freewheeling diode of main conversion circuit 201 in the power converter according to the present embodiment, leading to miniaturization of the power converter.

Although the present embodiment has described the example in which the present invention is applied to a two-level, three-phase inverter, the present invention is not limited thereto and is applicable to various power converters. Although a two-level power converter is used in the present embodiment, a three-level or multilevel power converter may be used, or the present invention is applicable to a single-phase inverter when power is supplied to a single-phase load. Alternatively, when power is supplied to a DC load or the like, the present invention is applicable to a DC/DC converter or an AC/DC converter.

The power converter to which the present invention is applied is not limited to the case described above where the load is an electric motor, and can be used as a power supply device of an electric discharge machine or a laser beam machine, or a dielectric heating utensil or a non-contact power feed system, and further, can be used as a power conditioner of a photovoltaic power generation system, a power storage system, or any other system.

It should be understood that the embodiments disclosed herein are illustrative and non-restrictive in every respect. At least two of the embodiments disclosed herein may be combined within the range where inconsistency does not occur. The scope of the present invention is defined by the terms of the claims, rather than the description of the embodiments above, and is intended to include any modifications within the scope and meaning equivalent to the terms of the claims.

### REFERENCE SIGNS LIST

1, 2 semiconductor chip; 1a first end; 1b second end; 3 control signal electrode; 4 control signal terminal; 4a fixed portion; 4b terminal portion; 4c bent portion; 4d position adjustment portion; 4e connection; 4f cutout; 5 joint member; 6 positioning member; 6a positioning portion; 6b, 25 recess; 6c opening; 7 main electrode; 8 chip bonding material; 9 circuit pattern; 10 first main terminal; 11, 13, 17 joint material; 12 second main terminal; 14 case; 15 insulating member; 16 metallic layer; 18 cooler; 19 sealing resin; 31 base member; 100 power supply; 200 power converter; 201 main conversion circuit; 202 semiconductor module; 203 control circuit; 300 load.

1. A semiconductor module comprising:
a base;
a semiconductor chip mounted on the base and including a control signal electrode;
a positioner disposed on the base and having a gap with an upper surface of the semiconductor chip and including a positioning portion that contacts an outer peripheral end portion of the semiconductor chip; and
a control signal terminal fixed to the positioner and connected to the control signal electrode.

2. The semiconductor module according to claim 1, wherein the positioner is fixed to the base.

3. The semiconductor module according to claim 1, wherein the control signal terminal includes
a fixed portion fixed to the positioner,
a terminal portion connected to the control signal electrode, and
a position adjustment portion that changes a position of the terminal portion relative to the fixed portion in a direction from the control signal electrode toward the terminal portion.

4. The semiconductor module according to claim 3, wherein
the control signal terminal includes a connection connecting the fixed portion to the terminal portion, and
the position adjustment portion includes a cutout formed in the connection.

5. The semiconductor module according to claim 3, wherein the position adjustment portion is a connection connecting the fixed portion to the terminal portion and being elastically deformable in the direction from the control signal electrode toward the terminal portion.

6. The semiconductor module according to claim 1, comprising a joint member joining the control signal electrode to the control signal terminal.

7. The semiconductor module according to claim 1, wherein the control signal electrode is directly joined to the control signal terminal.

8. The semiconductor module according to claim 1, wherein
the outer peripheral end portion of the semiconductor chip includes, in a plan view of the semiconductor chip,
a first end extending in a first direction, and
a second end extending in a direction crossing the first direction and being contiguous with the first end, and
the positioning portion includes
a first portion that contacts the first end, and
a second portion that contacts the second end.

9. The semiconductor module according to claim 1, wherein
in a plan view of the semiconductor chip, an outer shape of the outer peripheral end portion of the semiconductor chip is a quadrangular shape, and
the positioning portion contacts two or more adjacent sides in the outer shape of the outer peripheral end portion.

10. The semiconductor module according to claim 1, wherein the positioner has an opening for exposing a surface of the semiconductor chip on which the control signal electrode is formed.

11. A power converter comprising:
a main conversion circuit including a semiconductor module according to claim 1, the main conversion circuit converting received power and outputting the converted power; and
a control circuit that outputs a control signal for controlling the main conversion circuit to the main conversion circuit.
